(19) United States
(12) Patent Application Publication
(10) Pub. No.: US 2010/0319777 A1
(43) Pub. Date: Dec. 23, 2010

(54) SOLAR CELL AND METHOD OF FABRICATING THE SAME

(75) Inventors: Sung-Bum BAE, Daejeon (KR); Yong-Duck Chung, Daejeon (KR); Won Seok Han, Daejeon (KR); Dae-Hyung Cho, Seoul (KR); Je Ha Kim, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/604,450

(22) Filed: Oct. 23, 2009

(30) Foreign Application Priority Data
Jun. 19, 2009 (KR) 10-2009-0055080

(51) Int. Cl. H01L 31/0232; H01L 31/18

(52) U.S. Cl. 136/262; 438/69; 257/E31.119; 257/E31.127

(57) ABSTRACT

A solar cell and method of fabricating the same are provided. The solar cell includes a metal electrode layer, an optical absorption layer, a buffer layer, and a transparent electrode layer. The metal electrode layer is disposed on a substrate. The optical absorption layer is disposed on the metal electrode layer. The buffer layer is disposed on the optical absorption layer and includes an indium gallium nitride (InₓGa₁₋ₓN). The transparent electrode layer is disposed on the buffer layer.

### CROSS-REFERENCE TO RELATED APPLICATIONS

This U.S. non-provisional patent application claims priority under 35 U.S.C. §119 of Korean Patent Application No. 10-2009-0055080, filed on Jun. 19, 2009, the entire contents of which are hereby incorporated by reference.

### BACKGROUND OF THE INVENTION

The present invention disclosed herein relates to a solar cell and a method of fabricating the same, and more particularly, to a CIGS thin film solar cell and a method of fabricating the same.

With the growth of the solar cell market, thin film solar cells are attracting attention due to shortage of silicon raw material. Thin film solar cells may be divided into amorphous or crystalline silicon thin film solar cells, copper indium gallium selenide (CIGS) thin film solar cells, cadmium telluride (CdTe) thin film solar cells, and dye-sensitized solar cells according to materials. An optical absorption layer of a CIGS thin film solar cell includes I-III-VI₂ group compound semiconductors represented by CuInSe₂, and has a direct transition energy band gap and a high optical absorption coefficient, enabling the fabrication of highly-efficient solar cells with a thin film of about 1 μm to about 2 μm.

It is known that the efficiencies of CIGS solar cells are not only higher than some commercialized thin film solar cells such as CdTe but are also close to those of typical polycrystalline silicon solar cells. Additionally, compared to other types of solar cells, CIGS solar cells can be inexpensively fabricated, have enhanced flexibility, and have long-lasting performance.

### SUMMARY OF THE INVENTION

The present invention provides a solar cell that is easily fabricated and has improved efficiency, and a method of fabricating the same.

Embodiments of the present invention provide solar cells including: a metal electrode layer on a substrate; an optical absorption layer on the metal electrode layer; a buffer layer on the optical absorption layer, including an indium gallium nitride (InₓGa₁₋ₓN, 0<X<1); and a transparent electrode layer on the buffer layer.

In some embodiments, X may be reduced as the InₓGa₁₋ₓN becomes distant from the optical absorption layer.

In other embodiments, the InₓGa₁₋ₓN may have a value of and energy band gap between an energy band gap of the optical absorption layer and an energy band gap of the transparent electrode layer. Here, the energy band gap of the InₓGa₁₋ₓN may be increased as the InₓGa₁₋ₓN becomes distant from the optical absorption layer.

In still other embodiments, the solar cell may include a seed layer between the buffer layer and the optical absorption layer.

In even other embodiments, the seed layer may be formed of an indium nitride (InN).

In yet other embodiments, the optical absorption layer may include one of chalcopyrite compound semiconductors selected from a group consisting of CuInSe, CuInSe₂, CuInGaSe, and CuInGaSe₂.

In other embodiments of the present invention, methods of fabricating a solar cell include: forming a metal electrode layer on a substrate; forming an optical absorption layer on the metal electrode layer; forming a buffer layer on the optical absorption layer, including an InₓGa₁₋ₓN (0<X<1); and forming a transparent electrode layer on the buffer layer.

In some embodiments, the buffer layer may be formed through the same method as the optical absorption layer.

In other embodiments, the buffer layer may be formed through a co-evaporation method.

In still other embodiments, the optical absorption layer may be formed by co-evaporating indium (In), copper (Cu), selenium (Se), gallium (Ga) and nitrogen (N), and the buffer layer may be formed by co-evaporating In, Ga, and N.

In even other embodiments, X may be reduced as the InₓGa₁₋ₓN becomes distant from the optical absorption layer.

In yet other embodiments, an energy band gap of the InₓGa₁₋ₓN may be increased as the InₓGa₁₋ₓN becomes distant from the optical absorption layer.

In further embodiments, the method may further include forming a seed layer between the InₓGa₁₋ₓN and the optical absorption layer. Here, the forming of the seed layer includes alternately evaporating Se and N to perform a nitrogen treatment on a surface of the optical absorption layer, and forming an indium nitride (InN) by reacting N and In on the surface of the optical absorption layer.

In still further embodiments, the buffer layer and the transparent layer may have the same crystal structure.

In even further embodiments, the substrate may be loaded onto cluster equipment including a sputtering chamber and a co-evaporation chamber, the metal electrode layer and the transparent electrode layer are formed in the sputtering chamber, and the optical absorption layer and the buffer layer are formed in the co-evaporation chamber.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a diagram illustrating a copper indium gallium selenide (CIGS) thin film solar cell according to an embodiment;

FIG. 2 is a graph illustrating an energy band of a solar cell according to an embodiment;

FIG. 3 is a diagram illustrating an energy band of a solar cell according to a comparative example;

FIG. 4 is a diagram illustrating a CIGS thin film solar cell according to another embodiment;

FIG. 5 is a flowchart illustrating a method of fabricating a solar cell according to an embodiment;

FIG. 6 is a diagram illustrating a co-evaporation apparatus used for a method of fabricating a solar cell according to an embodiment; and

FIG. 7 is a diagram illustrating cluster equipment used for a method of fabricating a solar cell according to an embodiment.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the figures, respective components may be exaggerated for clarity of illustration. Like reference numerals refer to like elements throughout.

Meanwhile, for simplicity of description, several embodiments adopting the technical idea of the present invention will be exemplarily illustrated below, and description for various modified embodiments will be omitted herein. Hereinafter, the constitution and effect of the present invention will be more fully described according to specific embodiments and a comparative example, but it should be noted that the embodiments are merely provided to more clearly understand the present invention, not to limit the scope of the present invention.

Hereinafter, it will be described about an exemplary embodiment of the present invention in conjunction with the accompanying drawings.

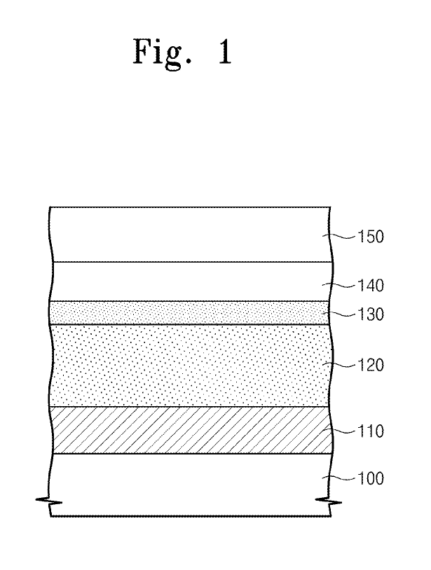

FIG. 1 is a diagram illustrating a copper indium gallium selenide (CIGS) thin film solar cell according to an embodiment.

Referring to FIG. 1, a metal electrode layer 110 is disposed on a substrate 100. The substrate 100 may be a soda lime glass substrate. The soda lime glass substrate is well-known as a relatively cheap substrate material. Also, the sodium of the soda lime glass substrate may be diffused into an optical absorption layer, thereby improving the photovoltage characteristics of the CIGS thin film solar cell. According to a modified embodiment, the substrate 100 may be a ceramic substrate such as aluminium, a metallic substrate such as a stainless steel and a copper tape, or a poly-film.

The metal electrode layer 110 may have low resistivity and excellent adhesion so that a peeling phenomenon by a mismatch of coefficients of thermal expansion may not occur. Specifically, the metal electrode layer 110 may be formed of molybdenum. The molybdenum may have high electrical conductivity, ohmic contact with other thin films, and high-temperature stability in an atmosphere of selenium (Se).

An optical absorption layer 120 is disposed on the metal electrode layer 110. The optical absorption layer 120 may include one of chalcopyrite compound semiconductors selected from a group consisting of CuInSe, CuInSe₂, CuInGaSe, and CuInGaSe₂.

A buffer layer 130 including an indium gallium nitride (InₓGa₁₋ₓN) is disposed on the optical absorption layer 120, where X is greater than 0 and smaller than 1. A transparent electrode layer 140 is disposed on the buffer layer 130. The energy band gap of the buffer layer 130 must be greater than the band gap of the optical absorption layer 120, and smaller than the band gap of the transparent electrode layer 140. The energy band gap of the buffer layer 130 may be varied with the composition ratio of InₓGa₁₋ₓN. That is, as X of InₓGa₁₋ₓN becomes smaller (increase of gallium), the energy band gap may be increased.

According to an embodiment, as InₓGa₁₋ₓN becomes more distant from the optical absorption layer 120 (or becomes closer to the transparent electrode layer 140), the composition ratio of InₓGa₁₋ₓN may be gradually increased. Thus, the energy band gap of InₓGa₁₋ₓN may be gradually increased as InₓGa₁₋ₓN becomes more distant from the optical absorption layer 120.

Because the energy band gap of InₓGa₁₋ₓN closer to the optical absorption layer 120 is relatively smaller, the band-offset at an interface between the absorption layer 120 and the buffer layer 130 may be reduced. Accordingly, electric charges generated by the sunlight may easily be moved, thereby increasing the efficiency of the solar cell.

The optical absorption layer 120 and the transparent electrode layer 140 may have lattice constants different from each other. In this case, the buffer layer 130, which is formed between the optical absorption layer 120 and the transparent electrode layer 140, alleviate the difference in lattice constant, thereby contributing an improvement of junction structure. The buffer layer 130 may have the same crystal structure as the transparent electrode layer 140. For example, the buffer layer 130 and the transparent electrode layer 140 may have a wurtzite crystal structure.

The transparent electrode layer 140 may be a material having high light transmittance and excellent electrical conductivity. For example, the transparent electrode layer 140 may be a zinc oxide (ZnO). The zinc oxide has a band gap of about 3.2 eV, and high light transmittance of about 80% or more. The zinc oxide may be doped with aluminium or boron to have a low resistance value. On the other hand, the transparent 140 may further include an Indium Tin Oxide (ITO) thin film having excellent electro-optical characteristics.

A reflection-preventing layer 150 may be disposed on the transparent electrode layer 140. The reflection-preventing layer 150 may reduce a reflection loss of the sunlight incident to a solar cell. The efficiency of the solar cell may be increased by the reflection-preventing layer 150. A grid electrode (not shown) may be disposed to be contacted with the transparent electrode layer 150. The grid electrode collects current from the surface of the solar cell. The grid electrode may be a metal such as Al. An area occupied by the grid electrode needs to be minimized because the sunlight is not transmitted through the area.

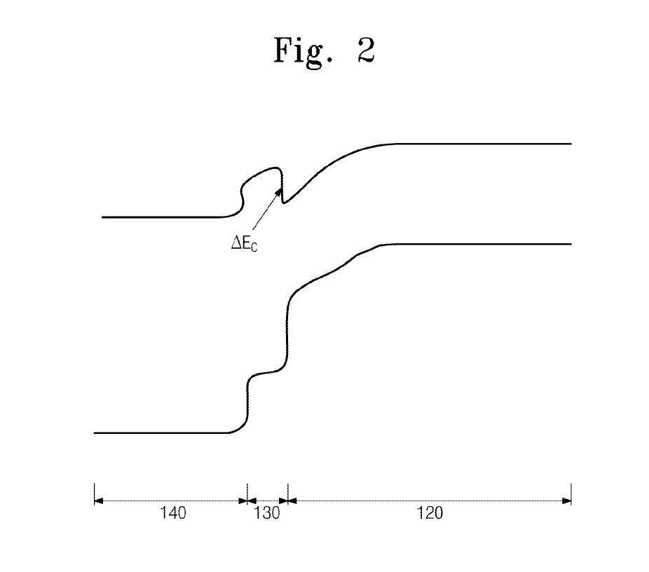

FIG. 2 is a graph illustrating an energy band of a solar cell according to an embodiment.

In FIG. 2, the optical absorption layer 120 is Cu(In, Ga)Se₂, the buffer layer 130 is InₓGa₁₋ₓN, and the transparent electrode layer 140 is ZnO. A P—N junction is formed between the optical absorption layer 120 and the transparent electrode layer 140. The energy band gap of the optical absorption layer 120 is about 1.2 eV, and the energy band gap of the transparent electrode layer 140 is about 3.2 eV. The energy band gap of the buffer layer 130 may range from about 1.2 eV to about 3.2 eV.

The energy band gap of the buffer layer 130 may be gradually increased as the buffer layer 130 becomes more distant from the optical absorption layer 120. A portion of the buffer layer 130 adjacent to the optical absorption layer 120 may have an energy band gap smaller than that of a portion of the buffer layer 130 adjacent to the transparent electrode layer 140. Accordingly, the band-offset Δ Ec of the conduction band may be reduced at the interface between the optical absorption layer 120 and the buffer layer 130. Electric charges generated by the sunlight may easily be moved, thereby increasing the efficiency of the solar cell.

Although it is not shown in FIG. 2 that the energy band gap or the conduction band is gradually changed, it will be understood by those skilled in the art that the energy band gap may be changed (or the band-offset Δ Ec of the conduction band may be reduced) according to the composition ratio of InₓGa₁₋ₓN thin film.

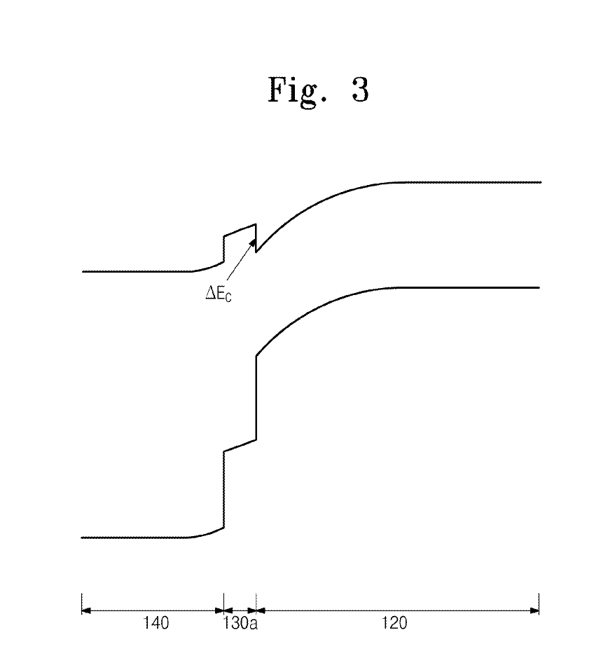

FIG. 3 is a diagram illustrating an energy band of a solar cell according to a comparative example. In this comparative example, an optical absorption layer 120 is Cu(In, Ga)Se₂, a buffer layer 130a is a Cadmium Sulfide (CdS), and a transparent electrode layer 140 is a ZnO film.

The CdS, the buffer layer 130a may have a constant energy band gap of about 2.4 eV. The band-offset Δ Ec of the conduction band is about 1.2 eV at the interface between the buffer layer 130a and the optical absorption layer 120. Electric charges generated in the optical absorption layer 120 by the sunlight may be difficult to move through a band-offset of about 1.2 eV. Particularly, electric charges generated by a long wavelength region of sunlight may be difficult to move through the band-offset because their energy is small. Accordingly, the efficiency of the solar cell including the buffer layer 130a formed of CdS may be reduced compared to the exemplary embodiment.

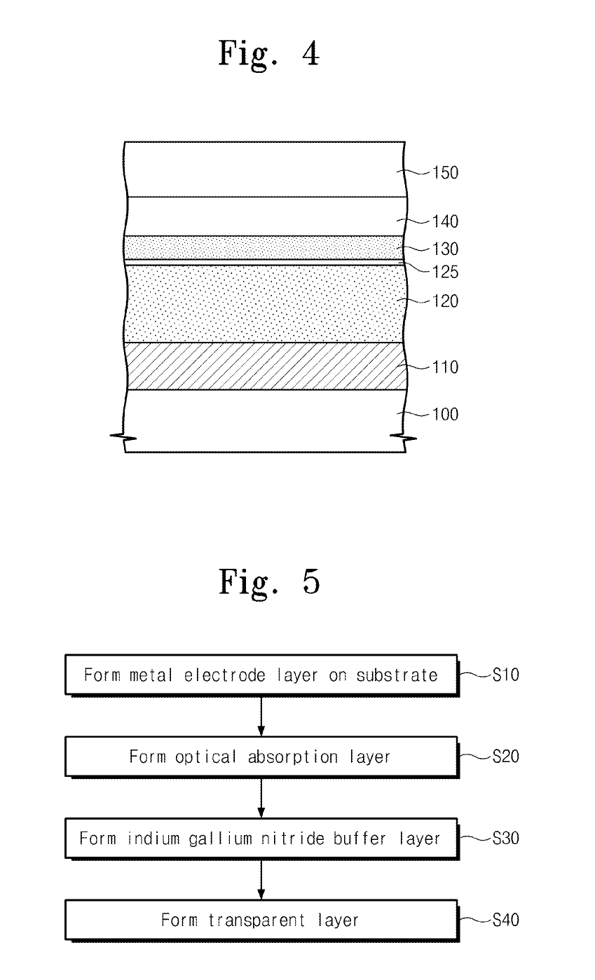

FIG. 4 is a diagram illustrating a CIGS thin film solar cell according to another embodiment.

Referring to FIG. 4, a metal electrode layer 110 is disposed on a substrate 100. The substrate 100 may be a soda lime glass substrate. The soda lime glass substrate is well-known as a relatively cheap substrate material. Also, the sodium of the soda lime glass substrate may be diffused into an optical absorption layer, thereby improving photovoltage characteristics of the CIGS thin film solar cell. According to a modified embodiment, the substrate 100 may be a ceramic substrate such as aluminium, a metallic substrate such as stainless steel and copper tape, or a poly-film.

The metal electrode layer 110 may have low resistivity and excellent adhesion so that a peeling phenomenon by a mismatch of coefficients of thermal expansion may not occur. Specifically, the metal electrode layer 110 may be formed of molybdenum. The molybdenum may have high electrical conductivity, ohmic contact with other thin films, and high-temperature stability in an atmosphere of selenium (Se).

An optical absorption layer 120 is disposed on the metal electrode layer 110. The optical absorption layer 120 may include one of chalcopyrite compound semiconductors selected from a group consisting of CuInSe, CuInSe₂, CuInGaSe, and CuInGaSe₂.

A buffer layer 130 including an indium gallium nitride (InₓGa₁₋ₓN) is disposed on the optical absorption layer 120, where X is greater than 0 and smaller than 1. A transparent electrode layer 140 is disposed on the buffer layer 130.

A seed layer 125 may be disposed between the buffer layer 130 and the optical absorption layer 120. The seed layer 125 may be an Indium Nitride (InN). The seed layer 125 may assist the buffer layer 130 to be continuously deposited on the optical absorption layer 120. In the case that the optical absorption layer 120 and the buffer layer 130 have a different crystal structure from each other, the seed layer 125 therebetween may contribute an improvement of junction structure.

The energy band gap of the buffer layer 130 may be, preferably, greater than the band gap of the optical absorption layer 120, and smaller than the band gap of the transparent electrode layer 140. The energy band gap of the buffer layer 130 may be varied with the composition ratio of InₓGa₁₋ₓN. That is, as X of InₓGa₁₋ₓN becomes smaller (increase of gallium), the energy band gap may be increased.

According to another embodiment, as InₓGa₁₋ₓN becomes more distant from the optical absorption layer 120 (or becomes closer to the transparent electrode layer 140), the composition ratio of InₓGa₁₋ₓN may be gradually increased. Thus, the energy band gap of InₓGa₁₋ₓN may be gradually increased as InₓGa₁₋ₓN becomes more distant from the optical absorption layer 120.

Because the energy band gap of InₓGa₁₋ₓN closer to the optical absorption layer 120 is relatively smaller, the band-offset at an interface between the absorption layer 120 and the buffer layer 130 may be reduced. Accordingly, electric charges generated by the sunlight may easily be moved, thereby increasing the efficiency of the solar cell.

The buffer layer 130 alleviates the difference in lattice constant between the optical absorption layer 120 and the transparent electrode layer 140, thereby contributing an improvement of junction structure. The buffer layer 130 may have the same crystal structure as the transparent electrode layer 140. For example, the buffer layer 130 and the transparent electrode layer 140 may have a wurtzite crystal structure.

The transparent electrode layer 140 may be a material having high light transmittance and excellent electrical conductivity. For example, the transparent electrode layer 140 may be a zinc oxide (ZnO). The zinc oxide has a band gap of about 3.2 eV, and high light transmittance of about 80% or more. The zinc oxide may be doped with aluminium or boron to have a low resistance value. According to a modified embodiment, the transparent 140 may further include an ITO thin film having excellent electro-optical characteristics.

A reflection-preventing layer 150 may be disposed on the transparent electrode layer 140. The reflection-preventing layer 150 may reduce a reflection loss of the sunlight incident to a solar cell. The efficiency of the solar cell may be increased by the reflection-preventing layer 150. A grid electrode (not shown) may be disposed to be contacted with the transparent electrode layer 150. The grid electrode collects current from the surface of the solar cell. The grid electrode may be a metal such as Al. An area occupied by the grid electrode needs to be minimized because the sunlight is not transmitted through the area.

According to another embodiment, the seed layer 125 may contribute to better junction between the buffer layer 130 and the optical absorption layer 120.

Also, the energy band gap of the buffer layer 125 is gradually increased to improve the efficiency of the solar cell.

FIG. 5 is a flowchart illustrating a method of fabricating a solar cell according to an embodiment.

Referring to FIGS. 1 and 5, in operation S10, a metal electrode layer 110 is formed on the substrate 100. The substrate 100 may be a soda lime glass substrate, a ceramic substrate such as aluminium, a metallic substrate such as stainless steel and copper tape, or a poly-film. According to an embodiment, the substrate 100 may be formed of a soda lime glass.

The metal electrode layer 110 may be formed through a sputtering method or an electron beam deposition method. The metal electrode layer 110 may have low resistivity and excellent adhesion so that a peeling phenomenon by a mismatch of coefficients of thermal expansion may not occur. Specifically, the metal electrode layer 110 may be formed of molybdenum. The molybdenum may have high electrical conductivity, ohmic contact with other thin films, and high-temperature stability in an atmosphere of selenium (Se). The metal electrode layer 110 may be formed to have a thickness of about 0.5 μm to about 1 μm.

In operation S20, an optical absorption layer 120 is formed on the metal electrode layer 110. The optical absorption layer 120 may be formed of one of chalcopyrite compound semiconductors selected from a group consisting of CuInSe, CuInSe₂, CuInGaSe, and CuInGaSe₂. These compound semiconductors may be called a CIGS thin film.

The optical absorption layer 120 may be formed through a co-evaporation method. The optical absorption layer 120 may be formed by co-evaporating In, Cu, Se, Ga, and N. Specifically, the CIGS thin film may be deposited using In, Cu, Ga, Se effusion cells and an N cracker. For example, the In effusion cell may be In₂Se₃, the Cu effusion cell may be Cu2Se, the Ga effusion cell may be Ga₂Se₃, and the Se effusion cell may be Se. The effusion cell may be a highly pure material of, for example, about 99.99% or more. When the optical absorption layer 120 is formed, the temperature of the substrate 100 may range from about 300° C. to about 600° C. . The optical absorption layer 120 may be formed to have a thickness of about 1 μm to about 3 μm. The optical absorption layer 120 may be formed to have a mono-or multi-layer.

In operation S30, a buffer layer 130 including InₓGa₁₋ₓN may be formed on the optical absorption layer 120, where X may be greater than 0, and smaller than 1. The buffer layer 130 may be formed using the same method as the optical absorption layer 120. The buffer layer 130 and the optical absorption layer 120 may be formed using a co-evaporation method. The buffer layer 130 may be formed of InₓGa₁₋ₓN by co-evaporating In, Ga, and N. InₓGa₁₋ₓN may be formed by controlling the ratio of Ga, In and N while maintaining the deposition temperature to be between about 300° C. and about 600° C. The buffer layer 130 may be formed to have a thickness of about 10 Å to about 1000 Å.

Meanwhile, the buffer layer 130 may be formed through an atomic layer deposition method, a chemical vapor deposition method, or a sputtering method.

When the buffer layer 130 is formed of a CdS thin film, the CdS thin film may be formed through a Chemical Bath Deposition (CBD) method. In this case, the technical issues may occur as described below.

The CBD method may have low reproducibility in forming thin film due to a wet process of mixing solutions, and cause characteristics changes of the thin film according to changes of the solution concentration. Also, a poisonous material, cadmium may cause an environmental pollution or a difficulty in processing. The CBD method may not be implemented in a consistent process with processes of forming the optical absorption layer 120 and the transparent electrode layer using a vacuum process. Since a low-temperature reaction around 100° C. is used in the CBD method, an already-formed thin film may be damaged in the subsequent processes. The method of forming the buffer layer 130 according to the embodiment can overcome the issues of the CBD method.

As described in FIG. 4, the seed layer 125 may be formed between the buffer layer 130 and the optical absorption layer 120. The seed layer 125 may be formed of InN. The forming of the seed layer 125 may include alternately evaporating Se and N to perform a nitrogen treatment on the surface of the optical absorption layer 120, and forming an indium nitride by reacting nitrogen and indium on the surface of the optical absorption layer 120. Se and N may be alternately evaporated while maintaining the deposition temperature at about 300° C. to about 600° C. . The maintenance time after a Se-atmosphere is converted into an N-atmosphere may be regulated within a range of about 60 minutes.

The seed layer 125 may assist the buffer layer 130 to be continuously deposited on the optical absorption layer 120. The seed layer 125 may contribute to better junction between the optical absorption layer 120 and the buffer layer 130 when they have a different crystal structure from each other.

The energy band gap of the buffer layer 130 must be greater than the band gap of the optical absorption layer 120, and smaller than the band gap of the transparent electrode layer 140. The energy band gap of the buffer layer 130 may be varied with the composition ratio of InₓGa₁₋ₓN. That is, as X of InₓGa₁₋ₓN becomes smaller (increase of gallium), the energy band gap may be increased.

According to an embodiment, as InₓGa₁₋ₓN becomes more distant from the optical absorption layer 120 (or becomes closer to the transparent electrode layer 140), the composition ratio of InₓGa₁₋ₓN may be gradually increased. Thus, the energy band gap of InₓGa₁₋ₓN may be gradually increased as InₓGa₁₋ₓN becomes more distant from the optical absorption layer 120.

Because the energy band gap of InₓGa₁₋ₓN closer to the optical absorption layer 120 is relatively smaller, the band-offset at an interface between the absorption layer 120 and the buffer layer 130 may be reduced. Accordingly, electric charges generated by the sunlight may easily be moved, thereby increasing the efficiency of the solar cell.

In operation S40, the transparent electrode layer 140 is formed on the buffer layer 130. The transparent electrode layer 140 may be a material having high light transmittance and excellent electrical conductivity. For example, the transparent electrode layer 140 may be a zinc oxide (ZnO). The zinc oxide has a band gap of about 3.2 eV, and high light transmittance of about 80% or more. The zinc oxide may be doped with aluminium or boron to have a low resistance value. On the other hand, the transparent 140 may further include an ITO thin film having excellent electro-optical characteristics.

The optical absorption layer 120 and the transparent electrode layer 140 may have lattice constants different from each other. In this case, the buffer layer 130, which is formed between the optical absorption layer 120 and the transparent electrode layer 140, alleviate the difference in lattice constant, thereby contributing an improvement of junction structure. The buffer layer 130 may have the same crystal structure as the transparent electrode layer 140. For example, the buffer layer 130 and the transparent electrode layer 140 may have a wurtzite crystal structure.

A reflection-preventing layer 150 may be disposed on the transparent electrode layer 140. The reflection-preventing layer 150 may reduce a reflection loss of the sunlight incident to a solar cell. The efficiency of the solar cell may be increased by the reflection-preventing layer 150. A grid electrode (not shown) may be disposed to be contacted with the transparent electrode layer 150. The grid electrode collects current from the surface of the solar cell. The grid electrode may be a metal such as Al. An area occupied by the grid electrode needs to be minimized because the sunlight is not transmitted through the area.

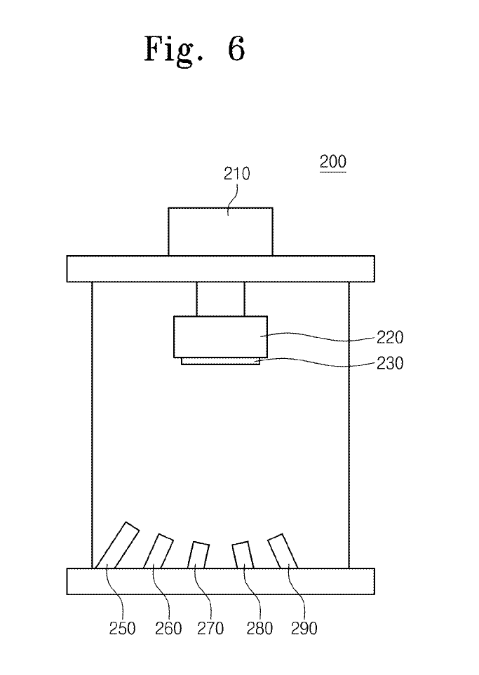

FIG. 6 is a diagram illustrating a co-evaporation apparatus used for a method of fabricating a solar cell according to an embodiment.

Referring to FIG. 6, a co-evaporation apparatus may include a substrate holder fixing a substrate in a chamber, a heater 220 heating the substrate, and a rotation motor 210 rotating the substrate. Also, the co-evaporation apparatus 200 include a Cu effusion cell 260, an In effusion cell 270, a Ga effusion cell 280, a Se effusion cell 290, and an N cracker 250.

The optical absorption layer (120 in FIG. 1) according to an embodiment may be formed by co-evaporating Cu, In, Ga, Se, and N, and the buffer layer (130 in FIG. 1) may be formed by co-evaporating In, Ga, and N.

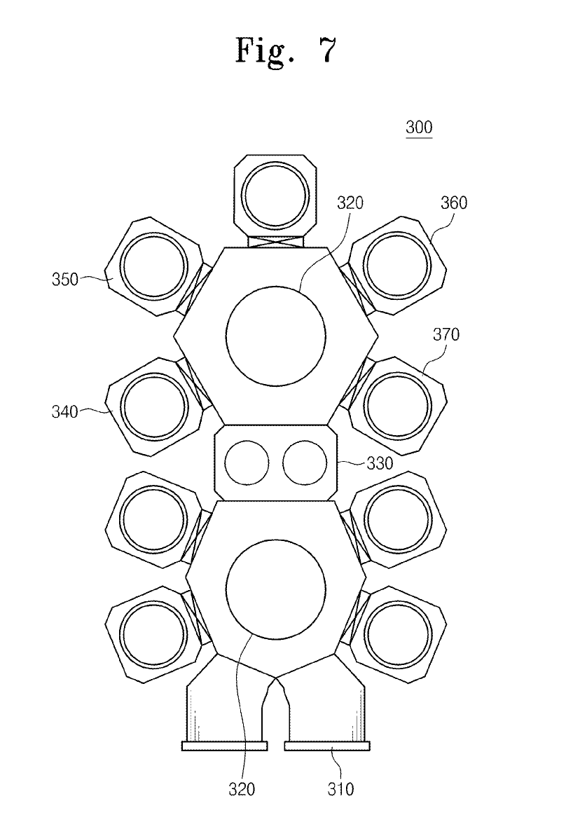

FIG. 7 is a diagram illustrating cluster equipment used for a method of fabricating a solar cell according to an embodiment.

Referring to FIG. 7, cluster equipment 300 includes a loadlock chamber 310, a transfer chamber 320, a cool down chamber 330, and processing chambers. The transfer chamber 320 includes a transfer apparatus transferring a substrate. The transfer apparatus may carry in and out the substrate between the processing chambers and the loadlock chamber 310. The cool down chamber 330 may reduce the temperature ascended in a deposition process. The processing chambers may include a sputtering chamber 340, a co-evaporation chamber 350, an atomic layer deposition chamber 360, and a chemical vapor deposition chamber 370.

Referring again to FIG. 1, the metal electrode layer 110, the optical absorption layer 120, the buffer layer 130, and the transparent electrode layer 140 according to an embodiment may be formed while maintained in a vacuum state. The substrate 100 may be load onto the cluster equipment including the sputtering chamber 340 and the co-evaporation chamber 350. The metal electrode layer 110 and the transparent electrode layer 140 may be formed in the sputtering chamber 340. The optical absorption layer 120 and the buffer layer 130 may be formed in the co-evaporation chamber 350. Thus, the metal electrode layer 110, the optical absorption layer 120, the buffer layer 130, and the transparent electrode layer 140 may be formed through a consistent process in a vacuum state. According to an embodiment, the yield of the solar cell may be increased due to the simplification of the fabrication process, and the fabrication cost may be reduced. Also, characteristics of thin films used in the solar cells may be enhanced.

On the other hand, according to another embodiment, the buffer layer 130 may be formed in the sputtering chamber 340, the atomic layer deposition chamber 360, or the chemical vapor deposition chamber 370. Since this process is performed through a consistent process in a vacuum state, the yield of a solar cell can be increased due to the simplification of the fabrication process, and the fabrication cost can be reduced.

According to the embodiments, the buffer layer of the solar cell is formed of an indium gallium nitride. The energy band gap of the indium gallium nitride may easily be regulated according to the composition ratio thereof. The band-offset of the conduction band may be reduced at the interface between the buffer layer and the optical absorption layer. Accordingly, electric charges generated by the sunlight may easily be moved, thereby increasing the efficiency of the solar cell.

According to the embodiments, the buffer layer of the solar cell may be formed through a co-evaporation method. The buffer layer may be formed of an indium gallium nitride, not a cadmium sulfide. Accordingly, the method of fabricating a solar cell according to an embodiment can reduce an environmental pollution, and form thin films through a consistent vacuum process.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A solar cell comprising:
a metal electrode layer on a substrate;
an optical absorption layer on the metal electrode layer;
a buffer layer on the optical absorption layer, the buffer layer comprising an indium gallium nitride (InₓGa₁₋ₓN, 0<X<1); and
a transparent electrode layer on the buffer layer.

2. The solar cell of claim 1, wherein the parameter X in the InₓGa₁₋ₓN decreases with increasing a distance from the optical absorption layer.

3. The solar cell of claim 1, wherein an energy band gap of the InₓGa₁₋ₓN is a value between energy band gaps of the optical absorption layer and the transparent electrode layer, the energy band gap of the InₓGa₁₋ₓN increasing as a distance from the optical absorption layer increases.

4. The solar cell of claim 1, further comprising a seed layer between the buffer layer and the optical absorption layer.

5. The solar cell of claim 4, wherein the seed layer is formed of an indium nitride (InN).

6. The solar cell of claim 1, wherein the optical absorption layer comprises one of chalcopyrite compound semiconductors selected from a group consisting of CuInSe, CuInSe₂, CuInGaSe, and CuInGaSe₂.

7. A method of fabricating a solar cell, comprising:
forming a metal electrode layer on a substrate;
forming an optical absorption layer on the metal electrode layer;
forming a buffer layer on the optical absorption layer, the buffer layer comprising an InₓGa₁₋ₓN (0<X<1); and
forming a transparent electrode layer on the buffer layer.

8. The method of claim 7, wherein the buffer layer is formed through the same method as the optical absorption layer.

9. The method of claim 7, wherein the buffer layer is formed through a co-evaporation method.

10. The method of claim 9, wherein the optical absorption layer is formed by co-evaporating indium (In), copper (Cu), selenium (Se), gallium (Ga) and nitrogen (N), and the buffer layer is formed by co-evaporating In, Ga, and N.

11. The method of claim 7, wherein the parameter X in the InₓGa₁₋ₓN is controlled to decrease with increasing a distance from the optical absorption layer.

12. The method of claim 7, wherein the InₓGa₁₋ₓN is formed to have an energy band gap increasing with a distance from the optical absorption layer.

13. The method of claim 7, further comprising forming a seed layer between the InₓGa₁₋ₓN and the optical absorption layer, wherein the forming of the seed layer comprises alternately evaporating Se and N to perform a nitrogen treatment on a surface of the optical absorption layer, and forming an indium nitride (InN) by reacting N and In on the surface of the optical absorption layer.

14. The method of claim 7, wherein the buffer layer and the transparent layer have the same crystal structure.

15. The method of claim 7, wherein the substrate is loaded onto cluster equipment comprising a sputtering chamber and a co-evaporation chamber, wherein the metal electrode layer and the transparent electrode layer are formed within the sputtering chamber and the optical absorption layer and the buffer layer are formed within the co-evaporation chamber.
